(19) United States
(12) Patent Application Publication
(10) Pub. No.: US 2026/0123383 A1
(43) Pub. Date: Apr. 30, 2026

(54) INTEGRATED CIRCUIT CHIP AND METHODS OF FABRICATION THEREOF

(71) Applicant: TAIWAN SEMICONDUCTOR MANUFACTURING COMPANY, LTD., Hsinchu (TW)

(72) Inventors: Chih-Chieh CHANG, Hsinchu (TW); Chih Hsin YANG, Hsinchu (TW); Kuan-Hsun WANG, Hsinchu (TW); Liang-Wei WANG, Hsinchu (TW)

(21) Appl. No.: 19/064,823

(22) Filed: Feb. 27, 2025

Related U.S. Application Data
(60) Provisional application No. 63/712,728, filed on Oct. 28, 2024.

(51) Int. Cl. H01L 23/522; H01L 21/768; H01L 23/00; H01L 23/528; H01L 23/58; H01L 25/07; H10D 30/00

(52) U.S. Cl. CPC H10W 20/42; H10W 20/023; H10W 20/435; H10W 42/00; H10W 90/00; H10D 30/501; H10W 90/26; H10W 90/297; H10W 90/792

(57) ABSTRACT

Embodiments of the present disclosure provide a semiconductor structure including Through Silicon Vias (TSVs) for delivering power from a backside power rail to a front side device layer and Feed Through Vias (FTVs) for delivering signals between a backside interconnect structures and a front side interconnect structure. The TSV provides reduces RC delays in the semiconductor structure.

### CROSS-REFERENCE TO RELATED APPLICATIONS

This application claims priority to the U.S. Provisional Patent Application Ser. No. 63/712,728 filed Oct. 28, 2024, which is incorporated by reference in its entirety.

### BACKGROUND

Conventionally, integrated circuits (IC) are built in a stacked-up fashion, having transistors at the lowest level and interconnect, such as vias and lines, on top of the transistors to provide connectivity to the transistors. Power rails, for example metal lines for voltage sources and ground planes, are also above the transistors and may be part of the interconnect. As the integrated circuits continue to scale down, so do the power rails. Scaling down of power rails inevitably leads to increased voltage drop across the power rails, as well as increased power consumption of the integrated circuits.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 1C, 1D, 1E, and 1F schematically illustrate a semiconductor structure according to embodiments of the present disclosure.

FIG. 2 is a flow chart of a method for manufacturing of a semiconductor structure according to embodiments of the present disclosure.

FIGS. 3A, 3B, 3C, 3D, 3E, 3F, 3G, 3H, and 3I schematically illustrate various stages of manufacturing a semiconductor structure according to embodiments of the present disclosure.

FIGS. 4A, 4B, and 4C schematically illustrate a package structure according to embodiments of the present disclosure.

FIGS. 5-13 schematically illustrates various package structures according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the semiconductor device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure describe an integrated circuit die having a device layer formed on a front side of a substrate, a front side interconnect structure over the device layer, a back side interconnect structure formed on a backside of the substrate, a through-silicon via (TSV) formed through the substrate and a portion of the front interconnect structure and a portion of the back interconnect structure. The backside interconnect structure includes a power rail, such as a super power rail (SPR). The integrated circuit die further includes a feed through via (FTV) formed in the substrate and connecting between the front side interconnect structure and the backside interconnect structure. The integrated circuit die may be used in a system on integrated chip (SoIC) packaging, in which a second die is stacked over the integrated circuit die. In some embodiments, the TSV may be used to deliver power directly to the second die. In some embodiments, the TSV is configured to deliver power, for example to deliver power from a package bump, such as an under bump metallization (UBM) connector to the second integrated circuit die stacked on the integrated circuit die. In some embodiment, the FTV is configured to transmit signals. For example, the FTV may be used to deliver signal from a UBM connector to the second die via a front side bond. Using TSVs in combination with SPR in SoIC packaging lowers RC delay and decouple power and signal delivery.

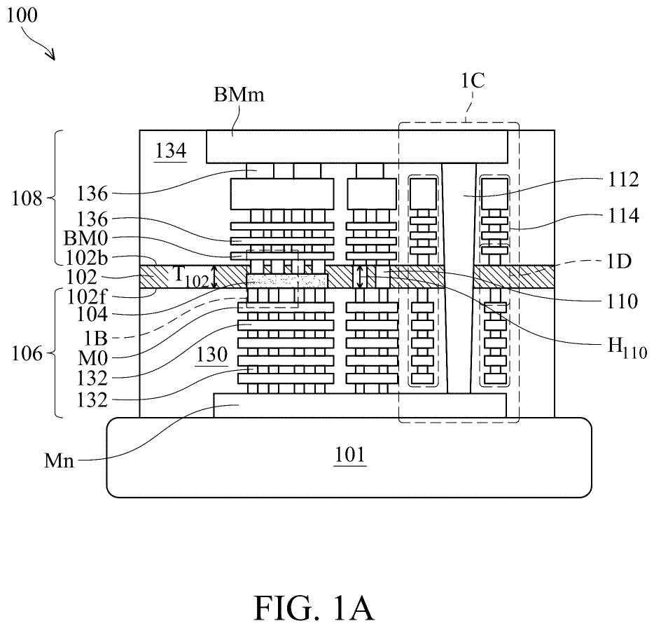

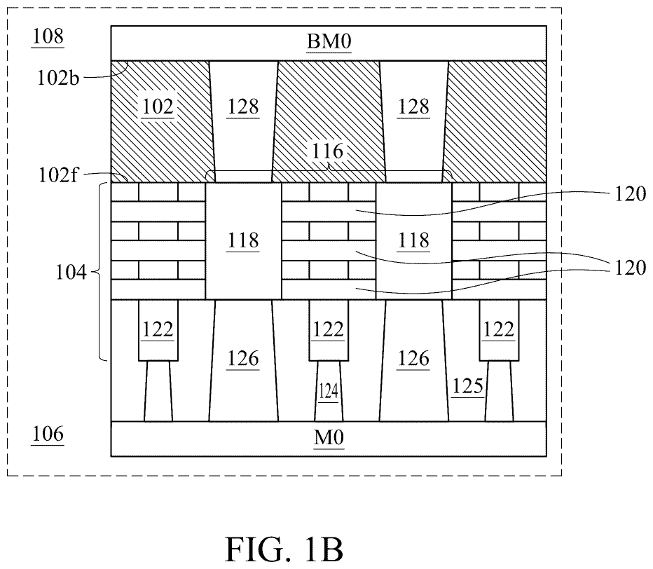

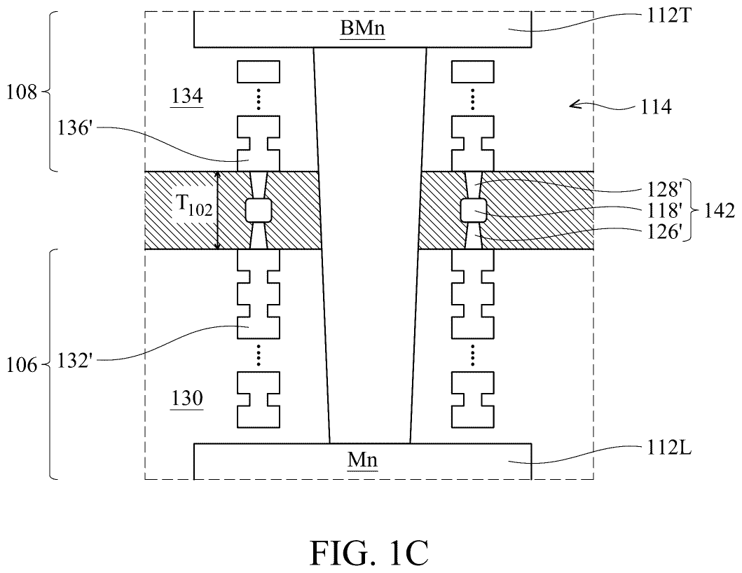

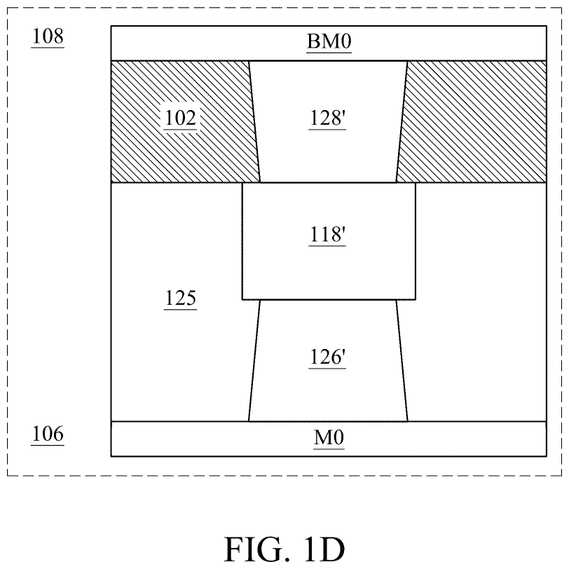

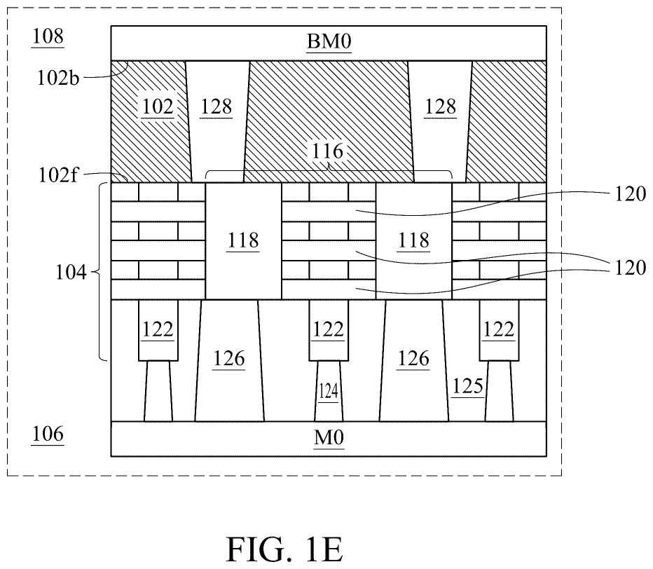

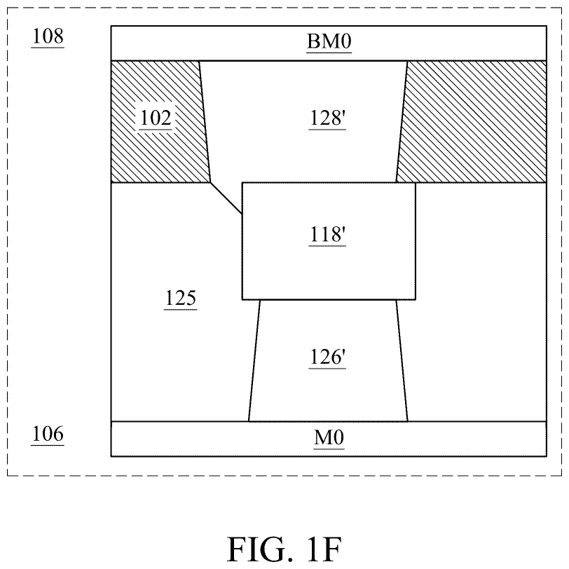

FIGS. 1A, 1B, 1C and 1D schematically illustrate an integrated circuit chip 100 according to embodiments of the present disclosure. FIG. 1A is a schematic cross section of the integrated circuit chip 100.

FIG. 1A illustrates the integrated circuit chip 100 disposed on a carrier wafer 101, which is attached to a front side of the integrated circuit chip 100 for backside processing. The carrier wafer 101 provides support during fabrication and packaging process and will be removed from the final products, for example, IC packages. As shown in FIG. 1A, the integrated circuit chip 100 includes a substrate 102, a device layer 104 is formed on a front side 102f of the substrate 102. A front side interconnect structure 106 is formed over the device layer 104 and the front side 102f of the substrate 102. A backside interconnect structure 108 is formed on a backside 102b of the substrate 102. The front side and backside interconnect structures 106, 108 include conductive lines and vias formed in dielectric layers and configured to provide electrical connection to structures formed in the substrate 102.

In some embodiments, the front side interconnect structure 106 includes one or more dielectric layers 130 having conductors 132 embedded therein. The conductors 132 include metal lines and vias arranged in layers. The conductors 132 are arranged in metallization patterns in layers and embedded in the dielectric layers 130. As shown in FIG. 1A, the conductors 132 may be arranged in n layers being M0, M1, M2, . . . Mn, n being an integer. The layer M0 is disposed the closest to the device layer 104 and the layer Mn is the topmost layer. The topmost layer Mn of the front side interconnect structure 106 may be embedded in a passivation layer made of one or more suitable dielectric materials such as silicon oxide, silicon nitride, low-k dielectrics, polyimide, combinations of these, or the like. In some embodiments, the passivation layer, e.g. the uppermost layer of the dielectric layers 130 of the front side interconnect structure 106, has openings exposing portions of a topmost layer of the metallization patterns for further electrical connection. In some embodiments, the front side interconnect structure 106 is electrically coupled to the device layer 104 for routing signals, e.g. electrical signals, power signals, and/or ground signals, thereto/therefrom.

In some embodiments, the backside interconnect structure 108 includes one or more dielectric layers 134 having conductors 136 embedded therein. The conductors 136 may include metal lines and vias arranged in layers. The conductors 136 are arranged in metallization patterns in layers and embedded in the dielectric layers 134. As shown in FIG. 1A, the conductors 136 may be arranged in m layers being BM0, BM1, . . . BMm, m being an integer. The layer BM0 is disposed the closest to the device layer 104 and the layer BMm is the topmost layer. The topmost layer BMn of the backside interconnect structure 108 may be referred to as top metal layer. The backside interconnect structure 108 is electrically coupled to the device layer 104 for routing signals, e.g. electrical signals, power signals, and/or ground signals, thereto/therefrom. In some embodiments, the backside interconnect structure 108 may include a backside power rail.

The dielectric layers 130, 134 may be polyimide (PI), polybenzoxazole (PBO), benzocyclobutene (BCB), a nitride, such as silicon nitride, an oxide, such as silicon oxide, PSG, borosilicate glass (BSG), BPSG, a combination thereof or the like, which may be patterned using a photolithography and/or etching process. In some embodiments, the dielectric layers 130, 134 are formed by suitable fabrication techniques such as spin-on coating, CVD (e.g. PECVD) or the like.

The conductors 132, 136 may be made of conductive materials, such as copper, copper alloy, aluminum, aluminum alloy, or combinations thereof. The conductive material may be formed by electroplating or deposition. The conductors 132, 136 fabricated in the dielectric layers 130, 134 using metallization process, for example damascene process. In some embodiments, the conductors 132, 136 are formed from one or more conductive materials. The conductive material may include copper, copper alloys, nickel, aluminum, manganese, magnesium, silver, gold, tungsten, a combination of thereof or the like. The conductive materials may be formed by, for example, electro-chemical plating process, CVD, such as plasma-enhanced chemical vapor deposition (PECVD), ALD, PVD, a combination thereof, or the like.

In some embodiments, one or more FTV conductors 110 are formed in the substrate 102. The FTV conductors 110 electrically connect the front side and backside interconnect structures 106, 108. The FTV conductors 110 may penetrate the substrate 102 to connect the front side and backside interconnect structures 106, 108. For example, the FTV conductors 110 are in contact between conductors 132 in the layer M0 of the front side interconnect structure 106 and conductors 136 in the layer BM0 of the backside interconnect structure 108. In some embodiments, the FTV conductors 110 has a height H₁₁₀ substantially the same as the thickness T₁₀₂ of the substrate 102. In some embodiments, the height H₁₁₀ of the FTV conductors is in a range between about 0.2 μm and about 0.5 μm. In some embodiments, the FTV conductors 110 may be fabricated during the backside processing prior to forming the backside interconnect structure 108. In some embodiments, dielectric liner or isolation layers maybe disposed between the substrate 102 and the FTV conductors 110. In some embodiments, the FTV conductors 110 may be used to transfer signals between the front side interconnect structure 106 and the backside interconnect structure 108.

In some embodiments, the integrated circuit chip 100 includes one or more TSV conductors 112. In some embodiments, each of the TSV conductors 112 is formed through at least a portion of the front side interconnect structures 106, the substrate 102, and at least a portion of the backside interconnect structures 108. In some embodiments, as shown in FIG. 1A, the TSV conductors 112 are connected between conductors in topmost layers of the front side and backside interconnect structures 106, 108. The topmost layers being the layers positioned farthest from the substrate 102. In some embodiments, the TSV conductors 112 are connected between a conductor 136 in the top metal layer BMm of the backside interconnect structure 108 and a conductor 132 in the topmost layer Mn of the front side interconnect structure 106 as shown in FIG. 1A.

Alternatively, the TSV conductors 112 are connected between conductors in other layers of the front side interconnect structure 106 and the backside interconnect structure 108. For example, the TSV conductors 112 are connected between a conductor 136 in the top metal layer BMm of the backside interconnect structure 108 and a conductor 132 in the middle layer Mn-x of the front side interconnect structure 106.

The TSV conductors 112 penetrate the substrate 102. The TSV conductors 112 may be formed during fabrication of the backside interconnect structure 108. For example, The TSV conductors 112 may be formed between formation of the layer BMm−1 and formation of the layer BMm. In some embodiments, dielectric liner or isolation layers maybe disposed around the TSV conductors 112.

In some embodiments, the TSV conductors 112 may be used to transfer power to a second integrated circuit chip vertically stacked over the integrated circuit chip 100. The second integrated circuit chip may be bonded to the integrated circuit chip 100 over the front side interconnect structure 106 or over the backside interconnect structure 108. The second integrated circuit chip may have the same structure or different structure.

In some embodiments, a seal structure 114 is formed around the TSV conductor 112. The seal structure 114 is configured to protect the device layer 104, and the dielectric layer 130, 134 and the conductors 132, 136 in the front side interconnect structure 106 and backside interconnect structure 108 during formation of the TSV conductors 112. The seal structure 114 may include conductive materials forming continuous structures in the dielectric layers 130, 134, and the substrate 102 around in the one or more TSV conductors 112.

FIG. 1B is a partial enlarged view of the integrated circuit chip 100 showing details of the device layer 104. In some embodiments, the device layer 104 includes various semiconductor devices configured to perform one or more circuit functions. In some embodiments, the device layer 104 may include a plurality of transistors 116. The transistors 116 and the front side and backside interconnect structures 106, 108 are interconnected to perform one or more functions including memory structures, e.g., a memory cell, processing structures, e.g., a logic cell, input/output (I/O) circuitry, e.g. an 1/O cell, or the like. It is appreciated that the number of the transistors 116 included in one semiconductor device and the number of the semiconductor devices included in the integrated circuit chip 100 are not limited in the disclosure, and each may be one or more than one. For example, there are one or more transistors 116 in one semiconductor device, and/or there are one or more semiconductor devices in one integrated circuit chip 100.

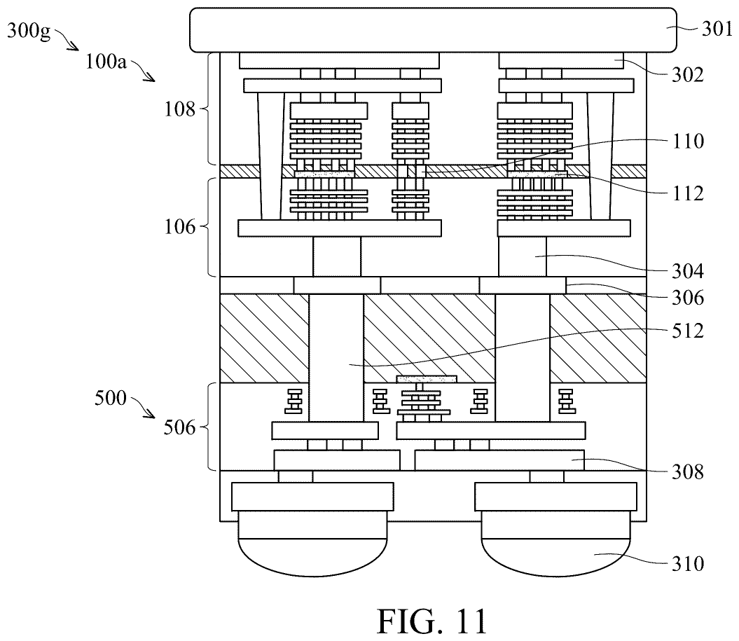

In FIG. 11B, a multi-channel transistor is shown. The transistor 116 includes two or more channel regions 120 formed over the front side 102f of the substrate 102. Source/drain regions 118 are formed on end portions of the channel regions 120, and a gate structure 122 is wrapped around the channel regions 120. Spacers, such as gate sidewall spacers (not shown) and inner spacers may be formed on the gate structures 122.

The substrate 102 may include a single crystalline semiconductor material such as, but not limited to Si, Ge, SiGe, GaAs, InSb, GaP, GaSb, InAIAs, InGaAs, GaSbP, GaAsSb, and InP. The substrate 102 may include various doping configurations depending on circuit design. For example, the substrate 102 includes a p-doped region or p-well and an n-doped region or n-well. One or more n-type devices, such as nFETs, are to be formed over and/or within p-well. One or more p-type devices, such as pFETs, are to be formed over and/or within n-well. In some embodiments, the p-well and the n-well may be separated by one or more insulation bodies, e.g., STI.

The channel regions 120 include semiconductor materials, for example epitaxially grown semiconductor layers. In some embodiments, the channel regions 120 may include silicon, Ge, a compound semiconductor such as SiC, GeAs, GaP, InP, InAs, and/or InSb, an alloy semiconductor such as SiGe, GaAsP, AIInAs, AlGaAs, InGaAs, GalnP, and/or GalnAsP, or combinations thereof.

The source/drain regions 118 may be epitaxially grown semiconductor material. The source/drain regions 118 may be doped for n-type devices and p-type devices. In some embodiments, the epitaxial source/drain regions 118 for n-type devices may include one or more layers of Si, SiP, SiC and SiCP. The epitaxial source/drain regions 118 for n-type devices may include N-type dopants, such as phosphorus (P), arsenic (As), etc. In some embodiments, the epitaxial source/drain regions 118 may be a Si layer includes phosphorus (P) dopants. The epitaxial source/drain regions 118 for the p-type devices may include one or more layers of Si, SiGe, Ge with p-type dopants, such as boron (B), for a p-type device, such as pFET. In some embodiments, the epitaxial source/drain regions 118 may be SiGe material including boron as dopant. The epitaxial source/drain regions 118 may be formed by any suitable method, such as by CVD, CVD epitaxy, molecular beam epitaxy (MBE), or any suitable deposition technique.

In some embodiments, the gate structure includes a gate dielectric layer and a gate electrode. The gate dielectric layer may include silicon oxide, silicon nitride, silicon oxy-nitride, high-k dielectric materials, or a combination thereof. It should be noted that the high-k dielectric materials are generally dielectric materials having a dielectric constant greater than 4 or even greater than about 10. High-k dielectric materials include metal oxides. Examples of metal oxides used for high-k dielectric materials include oxides of Li, Be, Mg, Ca, Sr, Sc, Y, Zr, Hf, Al, La, Ce, Pr, Nd, Sm, Eu, Gd, Tb, Dy, Ho, Er, Tm, Yb, Lu, and/or a combination thereof. In some embodiments, the gate dielectric layer is a high-k dielectric layer with a thickness in the range of about 10 to 30 angstroms. The gate dielectric layer is formed using a suitable process such as atomic layer deposition (ALD), chemical vapor deposition (CVD) such as flowable chemical vapor deposition (FCVD), physical vapor deposition (PVD), thermal oxidation, UV-ozone oxidation, or a combination thereof. The gate electrode may include a single-layered structure or a multi-layered structure. In some embodiments, the gate electrode may be a metal gate including metal, metal alloy, metal silicide or a combination thereof. Alternatively, the gate electrode may include semiconductor material. For example, the gate electrode may be made of undoped or doped polysilicon, amorphous silicon, or a combination thereof. The gate electrode may be formed by using a suitable process such as ALD, CVD, PVD, plating, or a combination thereof.

In some embodiments, the spacers are formed over sidewalls of the gate structures 122. The spacers may include silicon oxide, silicon nitride, silicon oxynitride, silicon carbide, fluoride-doped silicate glass (FSG), low-k dielectric materials, or a combination thereof. It should be noted that the low-k dielectric materials are generally dielectric materials having a dielectric constant lower than 3.9. The spacers may have a multi-layer structure which includes one or more liner layers. The liner layer includes a dielectric material such as silicon oxide, silicon nitride, and/or other suitable materials.

Various dielectric materials, such as insolation regions, inter-layer dielectric (ILD) layers, spacers, liners, contact etch stop layer (CESL), are formed between conductive and semiconductive materials of the transistors 116. These dielectric materials are not shown or marked in FIGS. 1A-1D for clarity.

Gate contacts 124 are disposed between the gate structures 122 and the conductors in the front side interconnect structure 106 or the backside interconnect structure 108. In some embodiments, as shown in FIG. 1B, the gate contacts 124 are embedded in the dielectric material 125 over the front side 102f of the substrate 102 and in contact with the conductors 132 of the front side interconnect structure 106. Particularly, the gate contacts 124 are in contact with the conductors 132 in the layer M0 of the front side interconnect structure 106.

In some embodiments, the source/drain regions 118 are connected to the front side interconnect structures 106 and/or the backside interconnect structures 108. In some embodiments, front side source/drain contacts 126 are formed between the source/drain regions 118 and the front side interconnect structure 106. Particularly, the front side source/drain contacts 126 penetrate the dielectric material on the front side 102f of the substrate 102 and are in contact with the conductors 132 in the layer M0 of the front side interconnect structure 106. In some embodiments, the front side source/drain contact 126 are electrically coupled to the source/drain regions 118 through silicide layers formed on the source/drain regions 118.

In some embodiments, backside source/drain contacts 128 are formed between the source/drain regions 118 and the backside interconnect structure 108. Particularly, the backside source/drain contacts 128 penetrate the substrate 102 and are in contact with the conductors 136 in the layer BM0 of the backside interconnect structure 108. Dielectric liner or isolation layers maybe disposed between the substrate 102 and the backside source/drain contacts 128. In some embodiments, the backside source/drain contact 128 are electrically coupled to the source/drain regions 118 through silicide layers formed on the source/drain regions 118. In some embodiments, the backside source/drain contact 128 may be connected to a power rail in the backside interconnect structure 108 to provide power to the transistors 116.

Even though, multi-channel transistors 116 are shown in FIG. 11B, the device layer 104 may include any suitable semiconductor devices, such as planar transistors, FinFET transistors, or the like.

FIG. 1E is a partial enlarged view of the integrated circuit chip 100 showing details of the device layer 104 in alternative embodiments. In some embodiments, the backside source/drain contacts 128 may be misaligned with the source/drain regions 118, as shown in FIG. 1E. In other embodiments, the backside source/drain contacts 128 and the front side source/drain contacts 126 may have different widths, as shown in FIG. 1E.

FIG. 1C is a partial enlarged view of the integrated circuit chip 100 showing details of a TSV conductor 112 and the seal structure 114 around the TSV conductor 112. FIG. 1D is a partial enlarged view of the integrated circuit chip 100 showing details of a portion of a seal structure 114 embedded in the substrate 102.

As shown in FIG. 1C, the TSV conductors 112 penetrate the substrate 102, and at least portions of the backside interconnect structure 108 and the front side interconnect structure 106. The TSV conductor 112 may be formed by etching the dielectric layer 134, the substrate 102, and the dielectric layer 130 to form a TSV opening and then filling the TSV opening with conductive material. To protect the components in the backside interconnect structure 108, the device layer 104, and the front side interconnect structure 106 from the processing chemistry, the seal structure 114 are formed around the TSV opening. The seal structure 114 is formed during fabrication of the device layer 104, the front side interconnect structure 106, and the backside interconnect structure 108.

The TSV conductor 112 is electrically connecting conductors in the top metal layer BMm of the backside interconnect structure 108 and conductors in the topmost layer Mn of the front side interconnect structures 106. As shown in FIG. 1C, the TSV conductor 112 is in contact with a top metal line 112T in the layer BMm of the backside interconnect structure 108. The TSV conductor 112 is in contact with a landing conductor 112L in the layer Mn of the front side interconnect structure 106. The top metal line 112T and the landing conductor 112L may be further connected to a power source or a power rail of another integrated circuit chip.

In some embodiments, the TSV conductors 112 has a height H₁₁₂. The height H₁₁₂ of the TSV conductors 112 is in a range between about 0.5 μm and about 10 μm. In some embodiments, the TSV conductor 112 is a via having a diameter CD₁₁₂. In some embodiments, the diameter CD₁₁₂ of the TSV conductor 112 is in a range between about 0.1 μm and about 15 μm. In some embodiments, the diameter CD₁₁₂ of the TSV conductor 112 may vary along the height. For example, the diameter CD₁₁₂ of the TSV conductor 112 near the top metal line 112T is greater than the diameter CD₁₁₂ of the TSV conductor 112 near the landing conductor 112L.

In some embodiments, the integrated circuit chip 100 may include TSV conductors of different sizes. For example, the integrated circuit chip 100 may include small size TSV conductors 112 having a diameter CD₁₁₂ in a range between about 0.1 μm and about 2 μm. The integrated circuit chip 100 may include middle size TSV conductors 112 having a diameter CD₁₁₂ in a range between about 2 μm and about 5 μm. The integrated circuit chip 100 may include large TSV conductors 112 having a diameter CD₁₁₂ in a range between about 5 μm and about 15 μm.

Different sizes of the TSV conductors 112 may be selected according to intended function, size of available area for TSV conductors in the circuit layout, or combination of other factors. For example, large size TSV conductors 112 may be selected to supply power across IC chips, middle and small sized TSV conductors 112 may be used to transfer signals between IC chips.

As shown in FIG. 1C, in the levels of the front side interconnect structure 106, the seal structure 114 includes conductors 132′ embedded in the dielectric layer 130 of the front side interconnect structure 106. The conductors 132′ may include lines and vias stacked in layers. The conductors 132′ are formed layer by layer with the conductors 132 in the front side interconnect structure 106. In some embodiments, the conductors 132′ in each layer may include a continuously line surrounding the TSV conductor 112 and vias connecting to the conductors 132′ in the adjacent layer.

In the levels of the backside interconnect structure 108, the seal structure 114 includes conductors 136′ embedded in the dielectric layer 134 of the backside interconnect structure 108. The conductors 136′ may include lines and vias stacked in layers. The conductors 136′ are formed layer by layer with the conductors 136 in the backside interconnect structure 108. In some embodiments, the conductors 136′ in each layer may include a continuously line surrounding the TSV conductor 112 and vias connecting to the conductors 136′ in the adjacent layer.

In some embodiments, the conductors 136′ and the conductors 132′ are connected by via structures 142 formed through the substrate 102. FIG. 1D schematically illustrates the via structure 142 according to some embodiments of the present disclosure. The via structure 142 may include a conductor via 126′, a semiconductor via 118′, and a conductor via 128′. The semiconductor via 118′ is similar to the source/drain regions 118 and may be formed with the same material and during the same time with the source/drain regions 118. In some embodiments, the semiconductor via 118′ may include epitaxially formed semiconductor material. In some embodiments, the semiconductor via 118′ may include doped semiconductor material. The conductor via 126′ connects between the semiconductor via 118′ and the conductors 132′ in the front side interconnect structure 106. The conductor via 126′ and the front side source/drain contacts 126 in the device layer 104 may be formed simultaneously and with the same material. The conductor via 128′ connects between the semiconductor via 118′ and the conductors 136′ in the backside interconnect structure 108. The conductor via 128′ and the backside source/drain contacts 128 in the device layer 104 may be formed simultaneously and with the same material.

In some embodiments, the seal structure 114 is electrically floating, i.e. the seal structure 114 is electrically isolated from other conductive structures in the integrated circuit chip 100, such as the TSV conductor 112, the conductors 132 in the front side interconnect structure 106, the conductors 136 in the backside interconnect structure 108, the source/drain contacts 126, 128, and the gate contacts 124. In some embodiments, as shown in FIG. 1C, the conductors 132′ are isolated from the landing conductor 112L by the dielectric layer 130. The conductors 136′ are isolated from the top metal line 112T by the dielectric layer 134.

FIG. 1F is a partial enlarged view of the integrated circuit chip 100 showing details of a portion of a seal structure 114 embedded in the substrate 102 in alternative embodiments. As shown in FIG. 1F, the bottom conductor via 128′ may be misaligned with the semiconductor via 118′ and partially cover a sidewall of the semiconductor via 118.

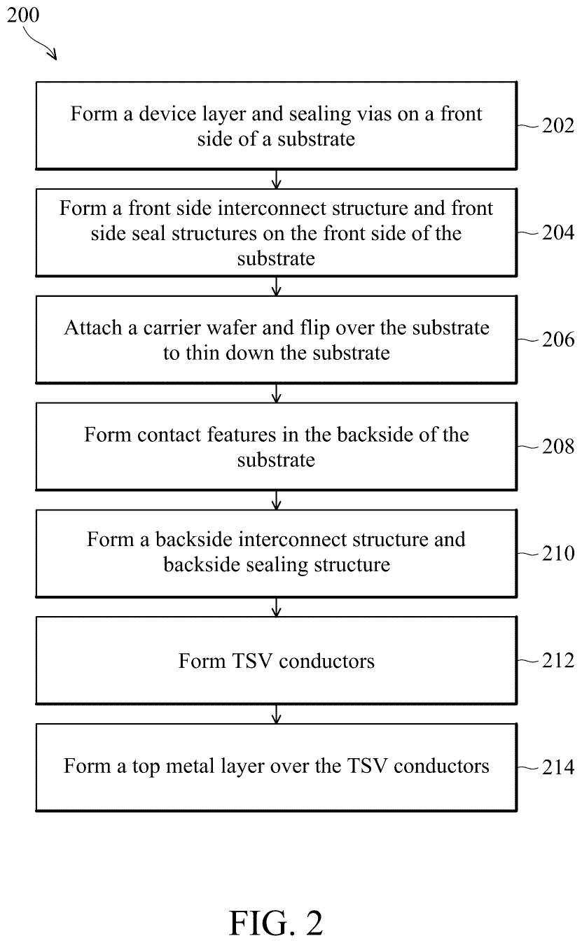

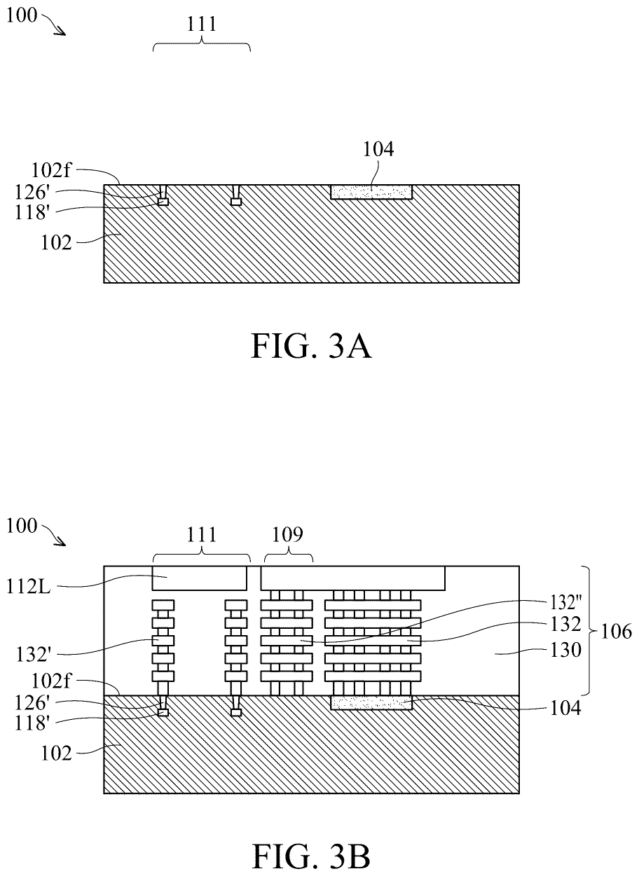

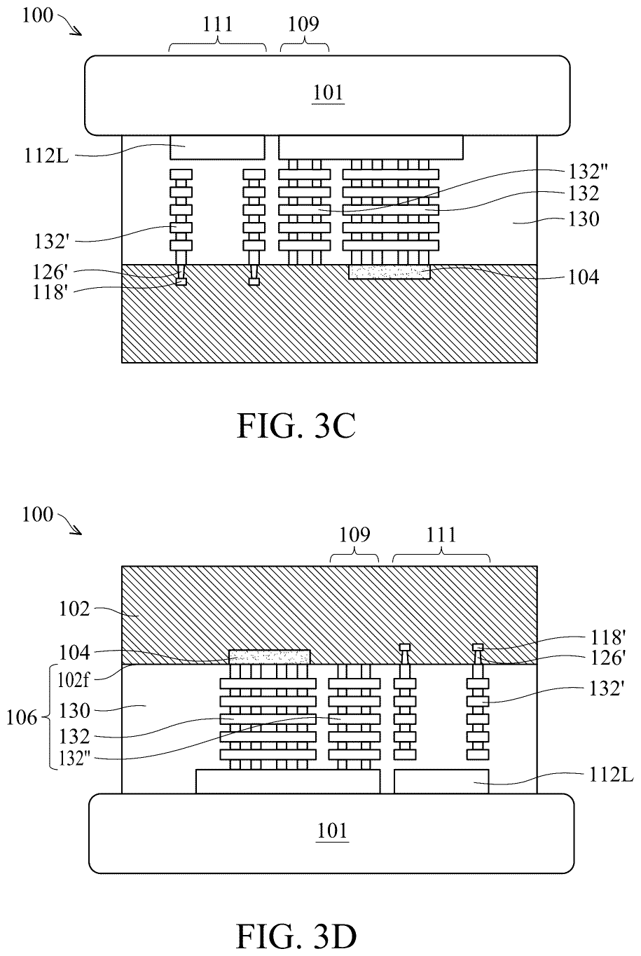

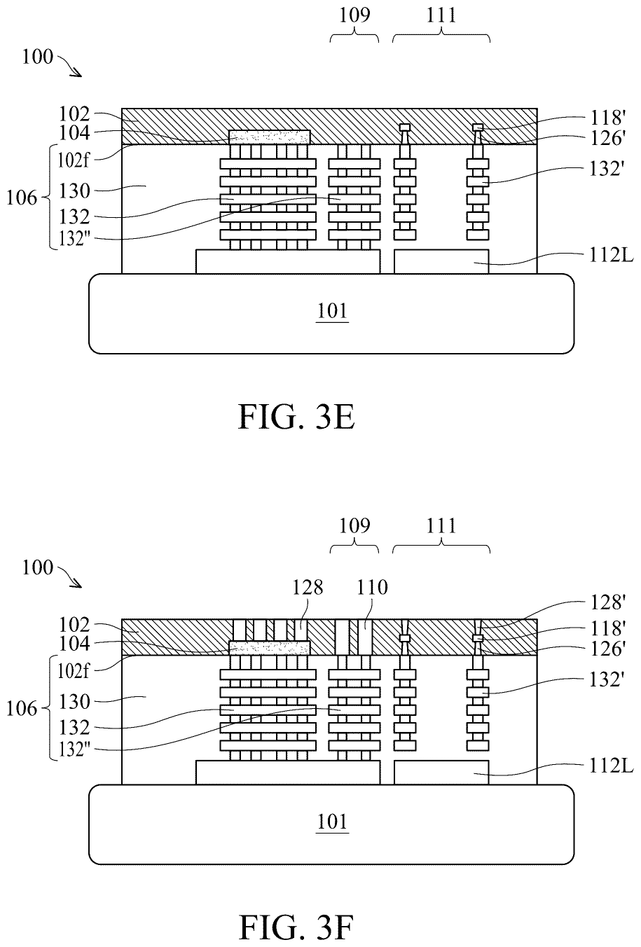

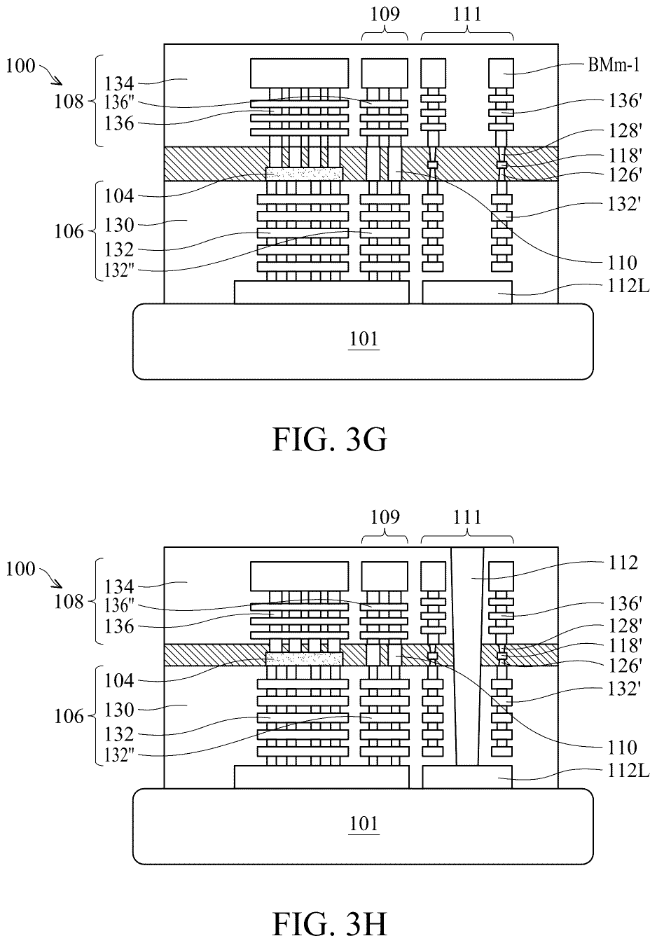

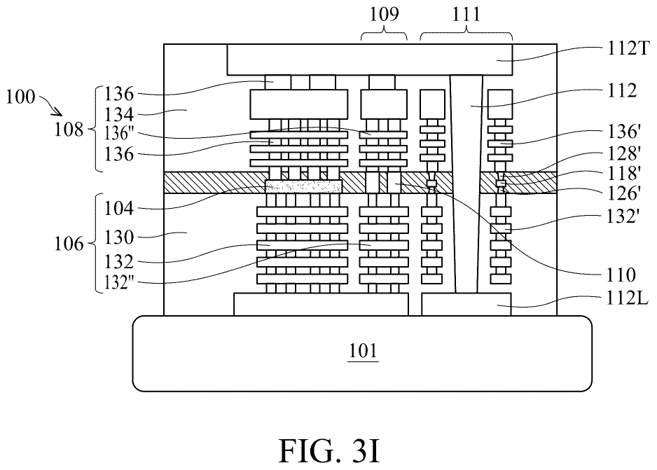

FIG. 2 is a flow chart of a method 200 for manufacturing of an integrated circuit chip according to embodiments of the present disclosure. FIGS. 3A-3I schematically illustrate various stages of manufacturing the integrated circuit chip 100 using the method 200.

In operation 202, a device layer and sealing vias for TSV conductors are formed on a front side of a substrate. FIG. 3A schematically illustrates integrated circuit chip 100 after operation 202. As shown in FIG. 3A, the device layer 104 are formed on the front side 102f of the substrate 102. The semiconductor vias 118′ and the conductor vias 126′ are also formed during the fabrication of the device layer 104. For example, the semiconductor vias 118′ may be fabricated during formation of the source/drain regions of the transistors in the device layer 104. The conductor vias 126′ may be formed during fabrication of the front side source/drain contacts. The conductor vias 126′ are stacked over the semiconductor vias 118′. In some embodiments, the conductor vias 126′ are in electrical connection with the semiconductor vias 118′. In some embodiments, a silicide layer may be formed between the semiconductor vias 118′ and the conductor vias 126′. The semiconductor vias 118′ and the conductor vias 126′ are formed around a TSV area 111, where the TSV conductor 112 is to be formed.

In operation 204, a front side interconnect structure and front side seal structure are formed. FIG. 3B schematically illustrates integrated circuit chip 100 after operation 204. As shown in FIG. 3B, the front side interconnect structure 106 is formed over the front side 102f of the substrate 102. The conductors 132 in the front side interconnect structure 106 are formed layer by layer over the device layer 104 to provide electrical connections to the device layer 104.

In some embodiments, the conductors 132′ for the seal structure 114 is formed layer by layer with the front side interconnect structure 106. The conductors 132′ include lines and vias stacked over the conductor vias 126′ and define the TSV area 111 within the front side interconnect structure 106. The conductor vias 126′ form a closed volume within the front side interconnect structure 106 under the topmost layer Mn where the landing conductor 112L is formed. The conductor vias 126′ are isolated from the topmost layer Mn so that the conductor vias 126′, i.e. the seal structure 114, are electrically isolated from the TSV conductor to be formed.

In the topmost layer Mn of the front side interconnect structure 106, the landing conductor 112L is formed in the TSV area 111. The landing conductor 112L is configured to connect with the TSV conductor to be formed. The landing conductor 112L may be a plate cover the TSV area 111.

In some embodiments, FTV conductors 132″ are formed in the front side interconnect structure 106. The FTV conductors 132″ may include conductive lines and vias in various layers of the front side interconnect structure 106. The FTV conductors 132″ form electrical paths to connect the FTVs to be formed through the substrate 102 in a FTV area 109. However, it should be noted that the FTV conductors 132″ may not be limited within the FTV area 109 in the front side interconnect structure 106. For example, the FTV conductors 132″ in the M0 level are disposed in the FTV area 109 so that the subsequently formed FTVs are in contact with the FTV conductors 132″ in the M0 level. However, the FTV conductors 132″ in the upper levels of the front side interconnect structure 106 may be disposed outside the FTV area 109 according to the circuit design.

In operation 206, a carrier wafer 101 is attached to the integrated circuit chip 100 as shown in FIG. 3C, and the integrated circuit chip 100 and the carrier wafer 101 are then flipped over, as shown in FIG. 3D. The substrate 102 is then grinded down from the backside for backside processing, as shown in FIG. 3E.

In operation 208, contact features, such as backside source/drain contacts, conductor vias for the seal structure, and FTVs, are formed in the backside of the substrate, as shown in FIG. 3F. FIG. 3F schematically illustrates integrated circuit chip 100 after operation 208. As shown in FIG. 3F, the backside source/drain contacts 128, the FTV conductors 110, and the conductor vias 128′ are formed in the substrate 102 from the backside 102b. The backside source/drain contacts 128 are disposed on the backside of the source/drain regions 118 in the device layer 104. The FTV conductors 110 are formed through the substrate 102 to connect with the FTV conductors 132″ in the front side interconnect structure 106. The conductor vias 128′ are disposed over the semiconductor vias 118′ for the seal structure 114. In some embodiments, the backside source/drain contacts 128, the FTV conductors 110, and the conductor vias 128′ may be formed at the same time by forming contact openings in the substrate 102 from the backside 102b of the substrate 102 and then filling the contact openings with a conductive material, such as a metal. A planarization process may be performed to expose the backside source/drain contacts 128, the FTV conductors 110, and the conductor vias 128′ on the backside 102b of the substrate 102.

In operation 210, a back side interconnect structure and back side seal structure are formed. FIG. 3G schematically illustrates integrated circuit chip 100 after operation 210. As shown in FIG. 3G, the backside interconnect structure 108 is formed over the backside 102b of the substrate 102. The conductors 136 in the backside interconnect structure 108 are formed layer by layer over back side contacts in the device layer 104 to provide electrical connections to the device layer 104.

In some embodiments, the conductors 136′ for the seal structure 114 is formed layer by layer with the backside interconnect structure 108. The conductors 136′ include lines and vias stacked over the conductor vias 128′ and define the TSV area 111 within the backside interconnect structure 108. The conductors 128″ form a closed volume within the backside interconnect structure 108.

In operation 210, the backside interconnect structure 108 is only partially formed. In some embodiments, the backside interconnect structure 108 is formed at one level below the top metal of the TSV conductor 112. For example, when the top metal plate of the TSV conductor 112 is located in the topmost level BMm of the backside interconnect structure 108, the backside interconnect structures 108 is formed to the level BMm−1 in operation 210.

In some embodiments, FTV conductors 136″ are formed in the backside interconnect structure 108. The FTV conductors 136″ may include conductive lines and vias in various layers of the backside interconnect structure 108. The FTV conductors 136″ form electrical paths to connect the FTV conductors 110 in the substrate 102. The FTV conductors 136″ in the BM0 level are disposed in the FTV area 109 so that the FTV conductors 110 are in contact with the FTV conductors 136″ in the BM0 level. However, the FTV conductors 136″ in the upper levels of the backside interconnect structure 108 may be disposed outside the FTV area 109 according to the circuit design.

In operation 212, TSV conductors are formed. FIG. 3H schematically illustrates integrated circuit chip 100 after operation 212. As shown in FIG. 3H, the TSV conductor 112 is formed in the TSV area 111. The TSV conductor 112 is formed through the substrate 102 and partially through the front side interconnect structure 106 and the backside interconnect structure 106.

After operation 212, the dielectric layer 134 covers the conductors 136, 136′ and 136″ so that the TSV conductor 112 may extend above the conductors 136, 136′ and 136″ for contacting conductors in the next level of the backside interconnect structure 108. The TSV conductor 112 may be formed by forming a TSV opening in the TSV area 111 through the backside interconnect structure 108, the substrate 102, and the front side interconnect structure 106 to expose the landing conductor 112L in the front side interconnect structure 106. The seal structure 114 surrounds the TSV opening and prevents components outside the TSV area 111 from exposing to the processing chemistry. The TSV opening is then filled with a conductive material, such as a metal, to form the TSV conductor 112. A planarization process may be performed to remove excessive conductive material and to expose the dielectric layer 134 and the TSV conductor 112 for subsequent processing. As shown in FIG. 3H, a top surface of the TSV conductor 112 extends above the conductors 136, 136′ and 136″.

In operation 214, a top metal layer is formed over the TSV conductor. FIG. 3I schematically illustrates integrated circuit chip 100 after operation 214. As shown in FIG. 3I, the top metal layer BMn of the backside interconnect structure 108 is formed over the TSV conductor 112. The top metal layer BMn includes conductive lines and vias to connect with the conductors 136 in the levels below. For example, The top metal layer BMn include lines and vias to the connect with the conductors 136 connected to the device layer 104 and the FTV conductors 136″. The top metal line 112T is formed in the TSV area 111 and is in contact with the TSV conductor 112. The conductor vias 128′ in the seal structure 114 are isolated from the top metal layer BMn so that the conductor vias 128′, i.e. the seal structure 114, are electrically isolated from the TSV conductor 112.

The integrated circuit chip 100 according to the present disclosure may be stacked with other integrated circuit chips in a 3DIC. The TSV conductors 112 of the integrated circuit chip 100 may be used to deliver power through the integrated circuit chip 100 stacked over and below the integrated circuit chip 100. For example, the TSV conductors 112 of the integrated circuit chip 100 may be used to deliver power from UMBs formed on one side of the integrated circuit chip 100 to another integrated circuit chip stacked on another side of the integrated circuit chip 100. In some embodiments, the FTV conductors 110 in the integrated circuit chip 100 may be used to deliver single to other integrated circuit chip stacked over the integrated circuit chip 100. Thus, the power and signal delivery may be decoupled.

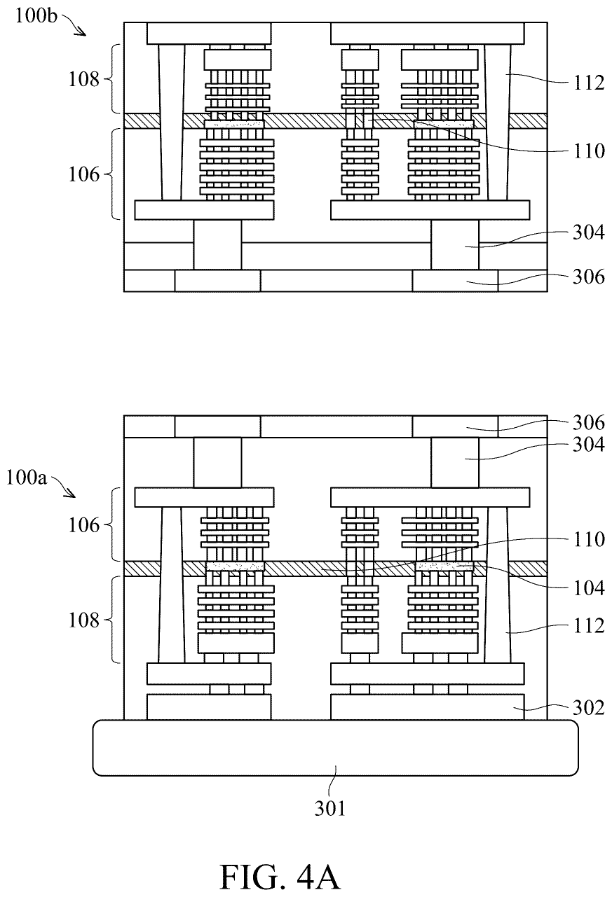

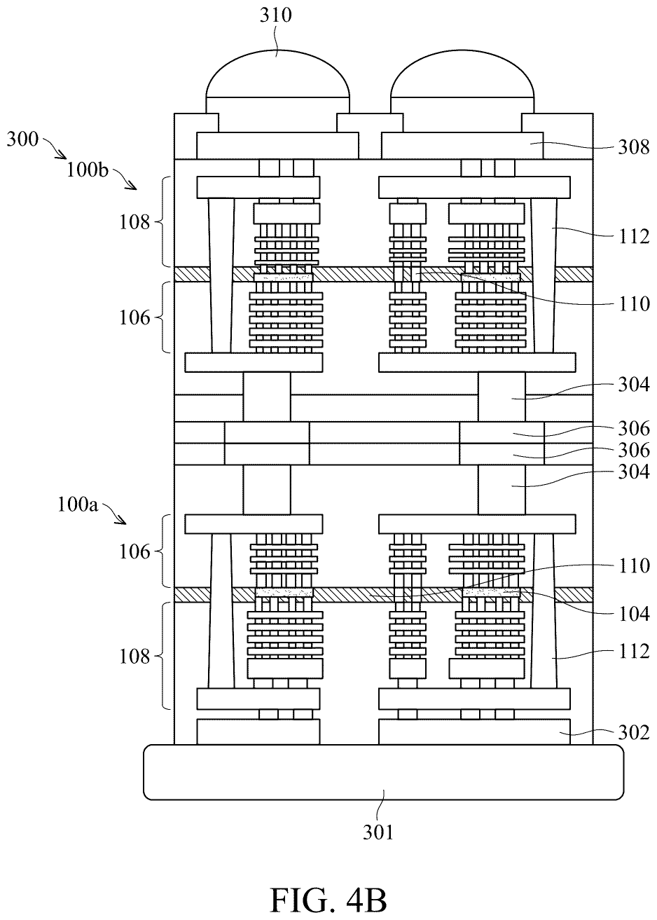

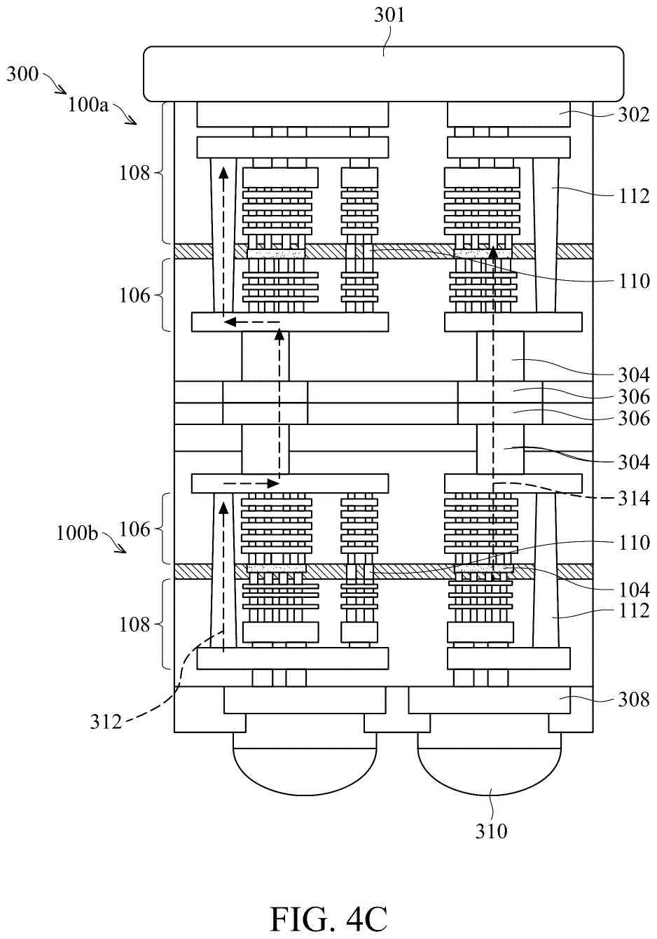

FIGS. 4A-4C schematically illustrate a package structure 300 according to embodiments of the present disclosure. The package structure 300 includes a first integrated circuit chip 100a and a second integrated circuit chip 100b. Both of the first integrated circuit chip 100a and the second integrated circuit chip 100b have similar structure to the integrated circuit chip 100 described above, having the front side interconnect structure 106, the backside interconnect structure 108, and the TSV conductors 112 formed through the substrate 102 and at least portions of the front side interconnect structure 106 and the backside interconnect structure 108. The backside interconnect structure 108 includes a backside power rail configured to supply power to the device layer 104 formed in the substrate 102.

In the package structure 300, the first integrated circuit chip 100a and the second integrated circuit chip 100b are vertically bonded with the front side interconnect structures 106 facing each other. FIG. 4A schematically illustrates the package structure 300 prior to bonding the first integrated circuit chip 100a and the second integrated circuit chip 100b.

In some embodiments, a redistribution layer (RDL) 302 may be formed over the backside interconnect structure 108 of the first integrated circuit chip 100a. The RDL 302 may be embedded in a passivation layer. The RDL 302 provides electrical connections to conductors in the top metal layer BMm. The first integrated circuit chip 100a is then attached to a carrier wafer 301 with the front side interconnect structure 106 facing up.

In some embodiments, a bonding film 304 is formed over the front side interconnect structure 106 of the first and second integrated circuit chips 100a, 100b. Bond pad features 306 are formed in the bonding film 304. In some embodiments, the bonding film 304 may be formed of silicon oxide, silicon oxynitride, silicon nitride, or low-k dielectric materials having k values lower than about 3.0. The low-k dielectric materials may include a carbon-containing low-k dielectric material, Hydrogen SilsesQuioxane (HSQ), MethylSilsesQuioxane (MSQ), or the like. In some embodiments, the bonding film 304 may be formed by suitable fabrication techniques such as chemical vapor deposition (CVD), High-Density Plasma Chemical Vapor Deposition (HDPCVD) or plasma-enhanced chemical vapor deposition (PECVD).

The bond pad features 306 may be formed of copper or other suitable metal to facilitate subsequent bonding. In some embodiments, the bond pad features 306 may be formed by suitable fabrication techniques such as electroplating or deposition. In some embodiments, the bond pad features 306 may be formed by a damascene process, such as a single damascene process or a dual-damascene process. The bond pad features 306 may be connected to the conductors 132 in the front side interconnect structure 106 by vias.

The bond pad features 306 of the first integrated circuit chip 100a are configured to bond with bond pad features 306 of the second integrated circuit chip 100b. In some embodiments, a top surface of the bond pad features 306 and a top surface of the bonding film 304 are substantially coplanar so as to provide an appropriate surface for the subsequent bonding. The planarity may be achieved, for example, through a planarization step such as a chemical mechanical polishing (CMP) step or a mechanical grinding step.

In FIG. 4B, the first integrated circuit chip 100a and the second integrated circuit chip 100b are bonded together. In some embodiments, the first integrated circuit chip 100a and the second integrated circuit chip 100b by a hybrid bonding process. In the hybrid bonding, the bond pad features 306 on the first integrated circuit chip 100a are bonded to the bond pad features 306 on the second integrated circuit chip 100b through metal-to-metal direct bonding while the bonding film 304 on the first integrated circuit chip 100a is bonded to the bonding film 304 on the second integrated circuit chip 100b through dielectric-to-dielectric bonding. In some embodiments, the metal-to-metal bonding at the hybrid bonding interface is copper-to-copper bonding. In some embodiments, the dielectric-to-dielectric bonding at the hybrid bonding interface is achieved with Si—O—Si bonds generated.

After bonding, a RDL 308 may be formed over the backside interconnect structure 108 of the second integrated circuit chip 100b. The RDL 308 provides electrical connections to conductors in the top metal layer BMm of the second integrated circuit chip 100b.

External connectors 310 are then formed over the RDL 308, as shown in FIG. 4B. The external connectors 310 may be contact bumps such as micro bumps or controlled collapse chip connection (C4) bumps. The external connectors 310 may comprise a material such as tin, or other suitable materials, such as silver or copper. In some embodiments, the external connectors 310 may be used to provide power or signals to the first integrated circuit chip 100a and the second integrated circuit chip 100b. In some embodiments, one or more external connectors 310 are connected to a power source.

FIG. 4C is a schematic view of the package structure 300 with the carrier wafer 301 flipped to the top. FIG. 4C schematically illustrates a power supply path 312 according to embodiments of the present disclosure. As shown in FIG. 4C, power supply to the first integrated circuit chip 100a may go through the power supply path 312, which starts from the external connectors 310, through the RDL 308, the TSV conductor 112 in the second integrated circuit chip 100b, the metal-to-metal bond between the bond pad features 306, the TSV conductor 112 in the first integrated circuit chip 100a to the backside interconnect structure 108 of the first integrated circuit chip 100a. The backside interconnect structure 108 of the first integrated circuit chip 100a includes a power rail configured to provide power to the device layer 104 of the first integrated circuit chip 100a. By going through the TSV conductors 112, the power supply path 312 has reduced RC.

In some embodiments, signals between the first integrated circuit chip 100a and the second integrated circuit chip 100b may be go through signal paths 314. A signal path 314 extends between the device layers 104 of the first integrated circuit chip 100a and the second integrated circuit chip 100b. As shown in FIG. 4C, the signal path 314 includes the conductors 132 in the front side interconnect structure 106 of the first integrated circuit chip 100a, the metal-to-metal bond between the bond pad features 306, and the front side interconnect structure 106 of the second integrated circuit chip 100b.

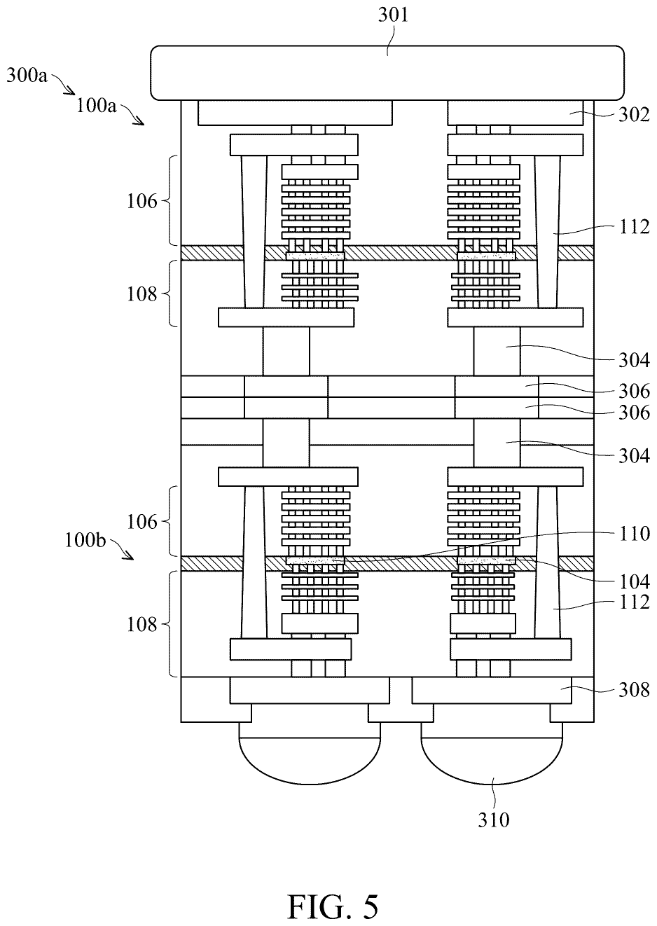

The integrated circuit chip 100 according to the present disclosure may be packaged with various arrangement. FIGS. 5-13 schematically illustrates various package structures according to embodiments of the present disclosure. In FIGS. 4A-4C and FIGS. 5-13, seal structures around the TSVs, such as the seal structure 114 are omitted for clarity. Additionally, when backside power rails are presented in an integrated circuit chip, FTVs are typically used for signal transmission. In FIGS. 5-13, FTVs are omitted in some integrated circuit chips with backside power rails for clarity.

FIG. 5 schematically illustrates a package structure 300a according to embodiments of the present disclosure. The package structure 300a is similar to the package structure 300 except that, in the package structure 300a, the backside interconnect structure 108 of the first integrated circuit chip 100a is bonded to the front side interconnect structure 106 of the second integrated circuit chip 100b. In the package structure 300a, power supply to the first integrated circuit chip 100a may start from the external connectors 310, through the RDL 308, the TSV conductor 112 in the second integrated circuit chip 100b, the metal-to-metal bond between the bond pad features 306 to the backside interconnect structure 108 of the second integrated circuit chip 100b.

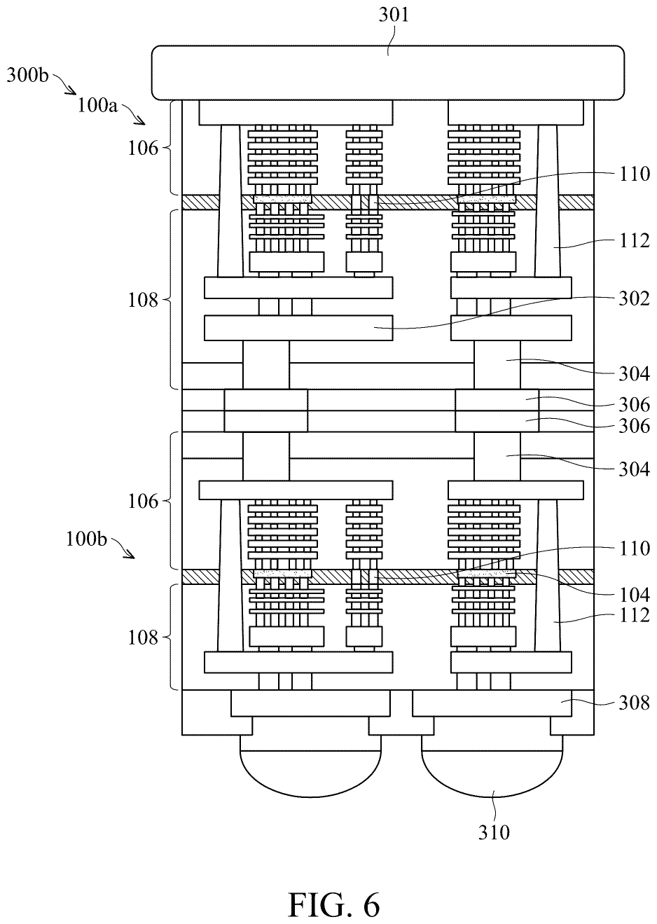

FIG. 6 schematically illustrates a package structure 300b according to embodiments of the present disclosure. The package structure 300b is similar to the package structure 300a except that, in the package structure 300b, the RDL 302 is disposed on the backside interconnect structure 108 of the first integrated circuit chip 100a. In the package structure 300b, power supply to the first integrated circuit chip 100a may start from the external connectors 310, through the RDL 308, the TSV conductor 112 in the second integrated circuit chip 100b, the metal-to-metal bond between the bond pad features 306, and the RDL 302 to the backside interconnect structure 108 of the second integrated circuit chip 100b.

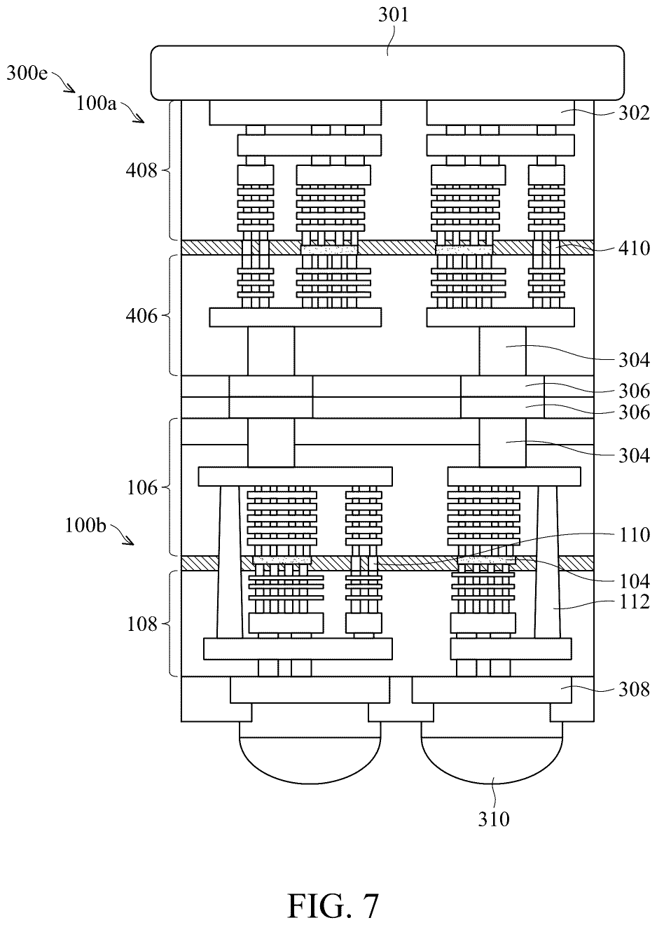

FIG. 7 schematically illustrates a package structure 300c according to embodiments of the present disclosure. The package structure 300c is similar to the package structure 300 except that, in the package structure 300c, the first integrated circuit chip 100a is replaced by an integrated circuit chip 400. The integrated circuit chip 400 includes a front side interconnect structure 406 and a backside interconnect structure 408. The backside interconnect structure 408 includes a power rail. However, the integrated circuit chip 400 does not include TSV between the front side interconnect structure 406 and the backside interconnect structure 408. Instead, FTVs 410 are formed between the front side interconnect structure 406 and the backside interconnect structure 408.

In the package structure 300c, the front side interconnect structure 106 of the second integrated circuit chip 100b is bonded to the front side interconnect structure 406 of the integrated circuit chip 400. In the package structure 300c, power supply to the integrated circuit chip 400 may start from the external connectors 310, through the RDL 308, the TSV conductor 112 in the second integrated circuit chip 100b, the metal-to-metal bond between the bond pad features 306, and the FTVs 410 in the integrated circuit chip 400 to the backside interconnect structure 408 of the integrated circuit chip 400.

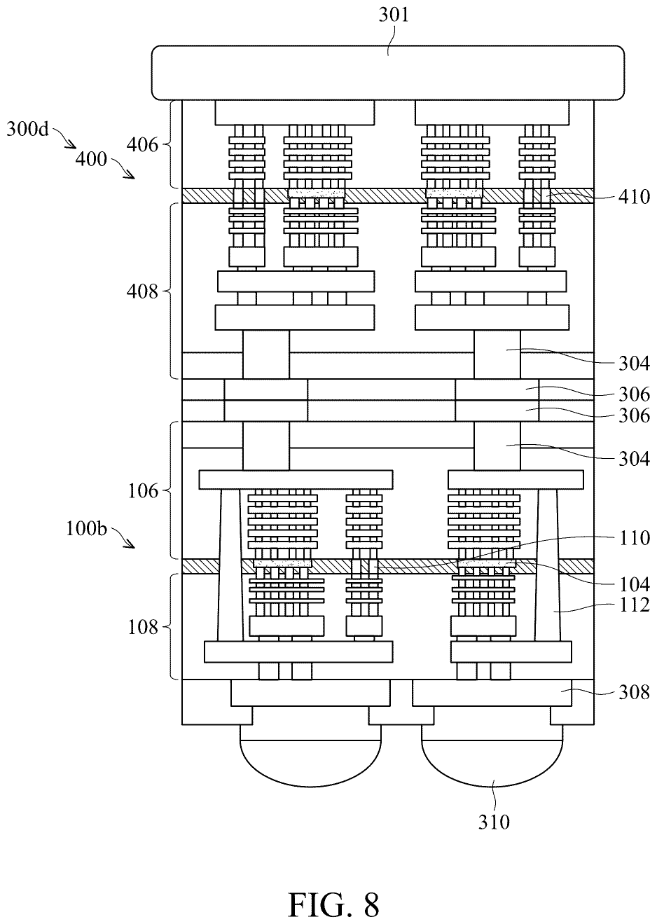

FIG. 8 schematically illustrates a package structure 300d according to embodiments of the present disclosure. The package structure 300d is similar to the package structure 300c except that, in the package structure 300d, the front side interconnect structure 106 of the second integrated circuit chip 100b is bonded to the backside interconnect structure 408 of the integrated circuit chip 400. In the package structure 300d, power supply to the integrated circuit chip 400 may start from the external connectors 310, through the RDL 308, the TSV conductor 112 in the second integrated circuit chip 100b, and the metal-to-metal bond between the bond pad features 306 to the backside interconnect structure 408 of the integrated circuit chip 400.

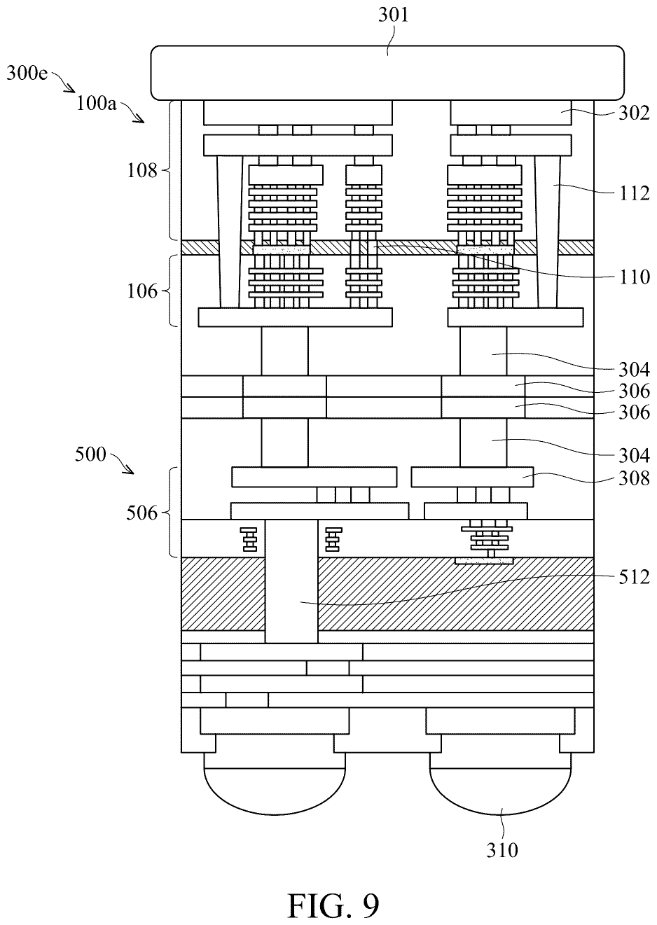

FIG. 9 schematically illustrates a package structure 300e according to embodiments of the present disclosure. The package structure 300e is similar to the package structure 300 except that, in the package structure 300e, the second integrated circuit chip 100b is replaced by an integrated circuit chip 500. The integrated circuit chip 500 includes a front side interconnect structure 506 and TSVs 512. However, the integrated circuit chip 500 does not include a backside interconnect structure or a backside power rail. The RDL 308 is formed over the front side interconnect structure 506.

In the package structure 300e, the front side interconnect structure 106 of the integrated circuit chip 100a is bonded to the front side interconnect structure 506 of the integrated circuit chip 500. In the package structure 300e, power supply to the first integrated circuit chip 100a may start from the external connectors 310, through the TSV 512 of the integrated circuit chip 500, the RDL 308, the metal-to-metal bond between the bond pad features 306, the TSV conductor 112 in the first integrated circuit chip 100a to the backside interconnect structure 108 of the first integrated circuit chip 100a.

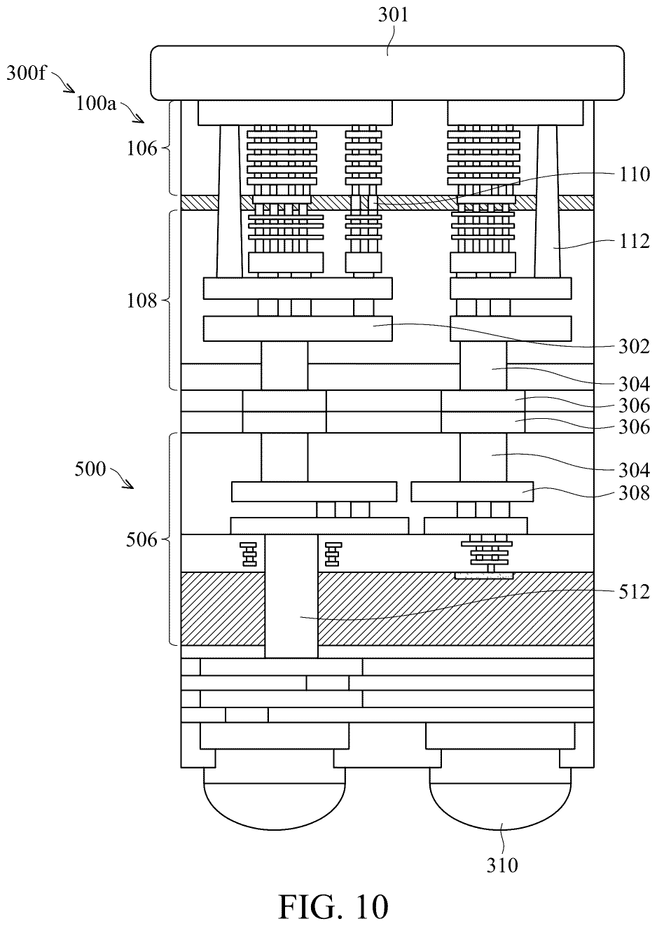

FIG. 10 schematically illustrates a package structure 300f according to embodiments of the present disclosure. The package structure 300f is similar to the package structure 300e except that, the backside interconnect structure 108 of the first integrated circuit chip 100a is bonded to the front side interconnect structure 506 of the integrated circuit chip 500. In the package structure 300f, power supply to the first integrated circuit chip 100a may start from the external connectors 310, through the TSV 512 of the integrated circuit chip 500, the RDL 308, and the metal-to-metal bond between the bond pad features 306, the RDL 302 to the backside interconnect structure 108 of the first integrated circuit chip 100a.

FIG. 11 schematically illustrates a package structure 300g according to embodiments of the present disclosure. The package structure 300g is similar to the package structure 300e except that, the first integrated circuit chip 100a is bonded to the backside of the integrated circuit chip 500. In the package structure 300g, the first integrated circuit chip 100a and the integrated circuit chip 500 are bonded with a hybrid bond having metal-to-metal bonds between the bond pad features 306 on the first integrated circuit chip 100a and the TSV 512 of the integrated circuit chip 500.

In the package structure 300g, power supply to the first integrated circuit chip 100a may start from the external connectors 310, the RDL 308, the TSV 512 of the integrated circuit chip 500, the metal-to-metal bond between the bond pad feature 306 and the TSV 512, the TSV conductor 112 of the first integrated circuit chip 100a to the backside interconnect structure 108 of the first integrated circuit chip 100a.

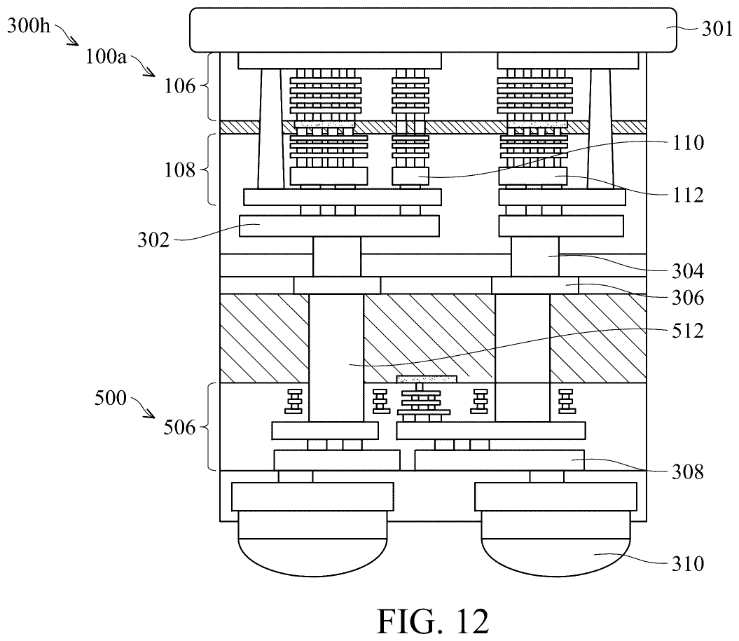

FIG. 12 schematically illustrates a package structure 300h according to embodiments of the present disclosure. The package structure 300h is similar to the package structure 300g except that, the backside interconnect structure 108 of the first integrated circuit chip 100a is bonded to the backside of the integrated circuit chip 500. In the package structure 300h, power supply to the first integrated circuit chip 100a may start from the external connectors 310, the RDL 308, the TSV 512 of the integrated circuit chip 500, the metal-to-metal bond between the bond pad feature 306 and the TSV 512, and the RDL 302 to the backside interconnect structure 108 of the first integrated circuit chip 100a.

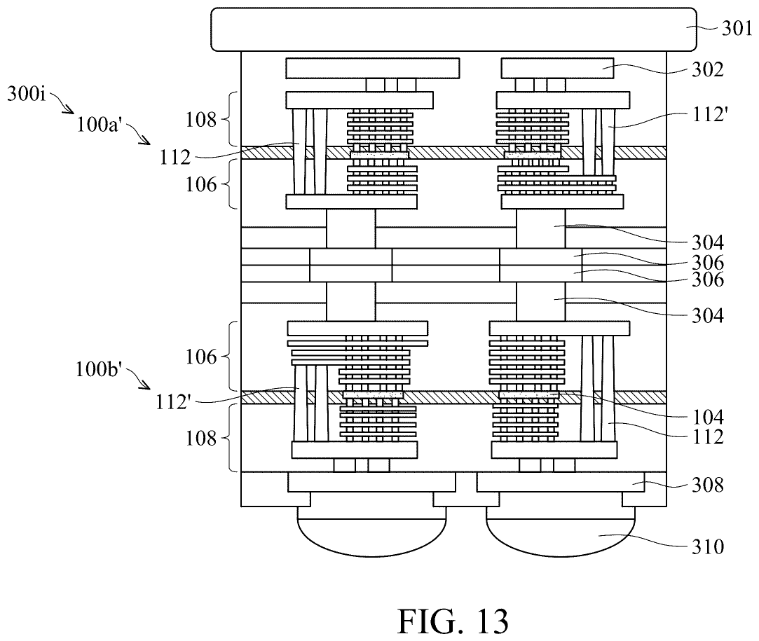

FIG. 13 schematically illustrates a package structure 300i according to embodiments of the present disclosure. The package structure 300i is similar to the package structure 300 except that, the package structure 300i includes a first integrated circuit chip 100a′ and a second integrated circuit chip 100b′ having short TSV connectors 112′ and/or clustered TSV conductors 112. The TSV connectors 112′ extend between the top metal layer BMn of the backside interconnect structure 108 and an intermediate layer Mx of the front side interconnect structure 106. The short TSV connectors 112′ provide flexibility in the circuit design. Additionally, the conductors 112 and the short TSV connectors 112′ may be formed in a cluster instead of a single TSV connector. The clustered TSV connectors may reduce process loading caused by the large CD of the TSV connectors relative to the conductors in the interconnect structures. It should be noted that short TSV connectors 112′ and/or the clustered TSV connectors 112 may be incorporated any of the package structures discussed above.

Various embodiments or examples described herein offer multiple advantages over the state-of-art technology. The integrated circuit chips according to the present disclosure include TSV connectors for delivering power to stacked circuit chips with reduced RC delay. Additionally, the integrated circuit chips include both TSV connectors and FTVs to decouple power and signal delivery, therefore, improve device performance.

Some embodiments of the present provide an integrated circuit chip, comprising: a substrate having a first side and a second side opposite to the first side; a device layer disposed on the first side of the substrate; a first interconnect structure disposed over the first side of the substrate, wherein the first interconnect structure comprises a plurality of first conductive layers; a second interconnect structure disposed over the second side of the substrate, wherein the second interconnect structure comprises a plurality of second conductive layers, and the second interconnect structure includes a power rail configured to transmit power to the device layer; and a through-silicon via (TSV) extending from one of the first conductive layers in the first interconnect structure, through the substrate, to one of the second conductive layers in the second interconnect structure.

Some embodiments of the present disclosure provide a package structure, comprises: a first integrated circuit chip comprising: a first substrate; a first device layer disposed on a front side of the first substrate; a first front side interconnect structure disposed over the front side of the first substrate; a first backside interconnect structure disposed over a back side of the first substrate, wherein the first backside interconnect structure includes a first power rail configured to transmit power to the first device layer; and a first through-silicon via (TSV) extending from the first front side interconnect structure, through the first substrate, and to the first backside interconnect structure; and a second integrated circuit chip stacked with the first integrated circuit chip, wherein a hybrid bonding surface is between the first integrated circuit chip and the second integrated circuit chip, the hybrid bonding surface comprises a metal-to-metal bonding, and the first TSV is in electrical connection with the metal-to-metal bonding.

Some embodiments of the present disclosure provide a method of fabricating an integrated circuit chip, comprising: forming a device layer on a first side of a substrate; forming a first interconnect structure over the device layer, wherein the first interconnect structure comprises a first seal structure around a through substrate via (TSV) area; forming a second interconnect structure on a second side of the substrate, wherein the second interconnect structure comprises a power rail configured to supply power to the device layer, and a second seal structure around the TSV area; and forming a TSV extending through the second interconnect structure and the substrate, and into the first interconnect structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An integrated circuit chip, comprising:
a substrate having a first side and a second side opposite to the first side;
a device layer disposed on the first side of the substrate;
a first interconnect structure disposed over the first side of the substrate, wherein the first interconnect structure comprises a plurality of first conductive layers;
a second interconnect structure disposed over the second side of the substrate, wherein the second interconnect structure comprises a plurality of second conductive layers, and the second interconnect structure includes a power rail configured to transmit power to the device layer; and
a through-silicon via (TSV) extending from one of the first conductive layers in the first interconnect structure, through the substrate, to one of the second conductive layers in the second interconnect structure.

2. The integrated circuit chip of claim 1, further comprising:
a feed through via (FTV) disposed in the substrate, wherein the FTV connects between the first interconnect structure and the second interconnect structure.

3. The integrated circuit chip of claim 2, wherein a height of the FTV is substantially equal to a thickness of the substrate.

4. The integrated circuit chip of claim 1, wherein a height of the TSV is greater than a thickness of the substrate.

5. The integrated circuit chip of claim 1, further comprising:
a first conductive plate disposed in the one of the first conductive layers; and
a second conductive plate disposed in the one of the second conductive layers, wherein a first end of the TSV is in contact with the first conductive plate, and a second end of the TSV is in contact with the second conductive plate.

6. The integrated circuit chip of claim 5, wherein the second conductive plate is disposed in a topmost layer of the second conductive layers.

7. The integrated circuit chip of claim 5, wherein the first conductive plate is disposed in a topmost layer of the first conductive layers.

8. The integrated circuit chip of claim 5, further comprising a seal structure formed in the first interconnect structure, the substrate and the second interconnect structure, wherein the seal structure surrounds the TSV.

9. The integrated circuit chip of claim 8, wherein the seal structure comprises a via structure in the substrate, the via structure comprises a first conductive via formed in the first side of the substrate, a second conductive via formed in the second side of the substrate, and a semiconductor via disposed between the first conductive via and the second conductive via.

10. The integrated circuit chip of claim 8, wherein the seal structure is electrically isolated from the first conductive plate and the second conductive plate.

11. The integrated circuit chip of claim 1, further comprising a cluster of TSVs.

12. A package structure, comprises:
a first integrated circuit chip comprising:
a first substrate;
a first device layer disposed on a front side of the first substrate;
a first front side interconnect structure disposed over the front side of the first substrate;
a first backside interconnect structure disposed over a back side of the first substrate, wherein the first backside interconnect structure includes a first power rail configured to transmit power to the first device layer; and
a first through-silicon via (TSV) extending from the first front side interconnect structure, through the first substrate, and to the first backside interconnect structure; and
a second integrated circuit chip stacked with the first integrated circuit chip, wherein a hybrid bonding surface is between the first integrated circuit chip and the second integrated circuit chip, the hybrid bonding surface comprises a metal-to-metal bonding, and the first TSV is in electrical connection with the metal-to-metal bonding.

13. The package structure of claim 12, wherein the second integrated circuit chip comprises:
a second substrate;
a second device layer disposed on a front side of the second substrate; and
a second front side interconnect structure disposed over the front side of the second substrate.

14. The package structure of claim 13, wherein the second integrated circuit chip further comprises:
a second TSV extending from the second front side interconnect structure through the second substrate, wherein the second TSV is in electrical connection with the first TSV.

15. The package structure of claim 14, wherein the hybrid bonding surface is between the first front side interconnect structure and the second front side interconnect structure.

16. The package structure of claim 14, wherein the second integrated circuit chip further comprises:
a second backside interconnect structure disposed over a backside of the second substrate, wherein the second TSV vertically extending from the second front side interconnect structure, through the second substrate, and to the second backside interconnect structure.

17. The package structure of claim 14, wherein the hybrid bonding surface is between the first backside interconnect structure and the second front side interconnect structure.

18. A method of fabricating an integrated circuit chip, comprising:
forming a device layer on a first side of a substrate;
forming a first interconnect structure over the device layer, wherein the first interconnect structure comprises a first seal structure around a through substrate via (TSV) area;
forming a second interconnect structure on a second side of the substrate, wherein the second interconnect structure comprises a power rail configured to supply power to the device layer, and a second seal structure around the TSV area; and
forming a TSV extending through the second interconnect structure and the substrate, and into the first interconnect structure.

19. The method of claim 18, further comprising:
prior to forming the second interconnect structure, forming a feed through via (FTV) through the substrate, wherein the FTV is in electrical connection with the first interconnect structure.

20. The method of claim 18, wherein forming the device layer comprises:
forming a semiconductor via in the substrate and a conductive via on the semiconductor via, wherein the first seal structure is subsequently formed over the conductive via.
